(19) United States
(12) Patent Application Publication
(10) Pub. No.: US 2012/0326030 A1
(43) Pub. Date: Dec. 27, 2012

(54) Particle Beam Microscope

(75) Inventors: Gerd Benner, Aalen (DE); Stefan Meyer, Aalen (DE); Steffen Niederberger, Gerstetten (DE); Dirk Preikszas, Oberkochen (DE)

(73) Assignee: CARL ZEISS NTS GMBH, Oberkochen (DE)

(21) Appl. No.: 13/337,268

(22) Filed: Dec. 26, 2011

(30) Foreign Application Priority Data
Dec. 27, 2010 (DE) 10 2010 056 321.8

(51) Int. Cl. H01J 37/26

(52) U.S. Cl. 250/310

(57) ABSTRACT

A particle beam microscope comprises a magnetic lens 3 having an optical axis 53 and a pole piece 21. An object 5 to be examined is mounted at a point of intersection 51 between an optical axis 53 and the object plane 19. First and second X-ray detectors 33 have first and second radiation-sensitive substrates 35 arranged such that a first elevation angle β₁ between a first straight line 55₁ extending through the point of intersection 51 and a centre of the first substrate 35₁ and the object plane 19 differs from a second elevation angle β₂ between a second straight line 55₂ extending through the point of intersection 51 and a centre of the second substrate 35₂ and the object plane 19 by more than 14°.

### CROSS-REFERENCES TO RELATED APPLICATIONS

The present application claims priority of German Patent Application No. 10 2010 056 321.8, filed Dec. 27, 2010, entitled “PARTICLE BEAM MICROSCOPE”, the contents of which is hereby incorporated by reference in its entirety.

### FIELD

The invention relates to particle beam microscopes having an energy dispersive X-ray detector.

### BACKGROUND

In such particle beam microscopes, X-ray radiation is generated by means of a focused particle beam generated by the particle beam microscope in an object to be inspected, wherein a spectrum of the X-ray radiation is recorded by the X-ray detector. From an analysis of the recorded X-ray spectrum, it is possible to deduce a composition of the object at the location of the incident particle beam. The particle beam microscope can be designed as an electron microscope, in particular a transmission electron microscope, or as an ion microscope, such as a helium gas field ion microscope, for example.

It has been found in conventional particle beam microscopes of this type that the X-ray spectra obtained during a reasonable measurement time have an excessively small number of detected X-ray events in order to determine the composition of the object at the location of the impinging particle beam with a desired significance.

### SUMMARY

Accordingly, it is an object of the present invention to provide a particle beam microscope having an X-ray detector allowing to evaluation recorded X-ray spectra with increased significance.

According to an embodiment, a particle beam microscope comprises a magnetic lens having an optical axis and at least one front pole piece arranged in the beam path along the optical axis at a distance upstream of an object plane, an object holder, which is configured for mounting an object to be examined at a point of intersection between the optical axis and the object plane, a first X-ray detector having a first radiation-sensitive substrate, and a second X-ray detector having a second radiation-sensitive substrate.

According to a particular embodiment herein, the first and second X-ray detectors are arranged such that a first elevation angle between a first straight line, which extends through the point of intersection and a centre of the first substrate, and the object plane differs from a second elevation angle between a second straight line, which extends through the point of intersection and a centre of the second substrate, and the object plane by more than 14°.

According to an exemplary embodiment, the first X-ray detector is arranged upstream of the object plane, as seen in the beam direction, on a side oriented towards the particle beam source, and the second X-ray detector is arranged downstream of the object plane on a side oriented away from the particle beam source.

According to further embodiments, the substrates of the first and second X-ray detectors are arranged at different elevation angles with respect to the object plane. This may have a consequence that the composition of the X-ray radiation impinging on the two substrates differs. Specifically, two types of X-ray radiation impinge on the substrates:

Firstly, this is the characteristic X-ray radiation which is generated by the particle beam impinging on the object as a result of excitation of electronic transitions in atoms and molecules of the object. The spectrum of characteristic X-ray radiation allows extract information relating to the composition of the object at a location of the incident particle beam. The characteristic X-ray radiation is emitted from the location of incidence of the particle beam on the object substantially isotropically, i.e. substantially uniformly distributed in the different spatial directions.

Secondly, this is the X-ray bremsstrahlung, which arises as a result of deflection of the particles impinging on the object in the electric field of atomic nuclei of the object. The X-ray bremsstrahlung is emitted anisotropically and with increased intensity in the forward direction from the point of view of the particle beam impinging on the object. The X-ray bremsstrahlung contributes to a background of a recorded X-ray spectrum, and the proportion of the recorded spectrum that is constituted by the spectrum of the characteristic X-ray radiation has to be calculated by subtracting this background.

Since the substrates of the two detectors are arranged at different elevation angles with respect to the object plane, substantially identical proportions of the substantially isotropically emitted characteristic X-ray radiation, but different proportions of the anisotropically emitted X-ray bremsstrahlung, impinge on the detectors, wherein identical distances between the substrates and the impingement location of the particle beam on the object are assumed. As a result, it is possible, by suitable analysis of the X-ray spectra recorded by the two detectors, to determine the respective proportion of X-ray bremsstrahlung impinging on the substrates with a comparatively high accuracy and to subtract it from the recorded spectra, such that the remaining portions of characteristic X-ray radiation can be calculated precisely, and the composition of the object at the impingement location of the particle beam can be determined therefrom with high significance. In this case, it is possible to determine not only the proportions of continuous bremsstrahlung but also, in particular, the portions of coherent bremsstrahlung occurring as peaks in the X-ray spectrum. Such peaks are generated by crystalline objects and it is particularly difficult to distinguish those from the continuous bremsstrahlung. Background information concerning coherent bremsstrahlung can be gathered from Chapter 33.4.C of the book Transmission Electron Microscopy: A Textbook for Materials Science (4-Vol Set): David B. Williams, C. Barry Carter, Spectrometry IV, 1996, Plenum Press, New York. From the spectra recorded by the detectors arranged at different elevation angles, the proportions of continuous bremsstrahlung and coherent bremsstrahlung can be determined separately in each case.

Moreover, the number of two detectors arranged near the location of incidence of the particle beam on the object allows the detection of an increased number of X-ray quanta and thus a shortening of the required measurement time.

In accordance with a further embodiment herein, a third and a fourth X-ray detector, and if appropriate even further X-ray detectors, are also provided, which can likewise be arranged at different elevation angles with respect to the object plane and which, however, are arranged, as seen about the optical axis, at different azimuth angles by comparison with the substrates of the first and second X-ray detectors. In particular, the substrate of the third X-ray detector can be arranged in a manner lying diametrically opposite the substrate of the first X-ray detector with respect to the point of intersection between the optical axis and the object plane. Likewise, the substrate of the fourth X-ray detector can be arranged in a manner lying diametrically opposite the substrate of the second X-ray detector with respect to the point of intersection.

In accordance with a further embodiment, a particle beam microscope comprises a magnetic lens having an optical axis, which comprises a front pole piece, which is arranged in the beam path along the optical axis at a distance upstream of an object plane, and a rear pole piece, which is arranged in the beam path along the optical axis at a distance downstream of the object plane, an object holder, which is configured for mounting an object to be examined at a point of intersection between the optical axis and the object plane, a first X-ray detector having a first radiation-sensitive substrate, and a second X-ray detector having a second radiation-sensitive substrate, wherein provision is furthermore made of an actuator, or drive, and a shutter, which can be moved from a first position into a second position by the actuation of the actuator and which is configured such that the shutter in the first position is arranged between the point of intersection between the optical axis and the object plane and both the first and the second substrate, in order to block impingement of X-ray radiation and stray particles emerging from the object that can be arranged at the point of intersection on the first and second substrates, and in the second position is arranged such that the X-ray radiation and stray particles emerging from the object that can be arranged at the point of intersection can impinge on the first and the second substrate.

In some operating situations there is the risk of the substrates of the detectors being contaminated by contaminations or being exposed to an excessively high dose of electrons. This is the case, for example, when a beam current of the particle beam impinging on the object is very high and detaches particles from the object or the particle beam microscope is operated with low magnetic excitation of the objective lens, such that in the region of the object an excessively low magnetic field is present for avoiding the impingement of excessively high electron intensities on the detectors.

In such operating situations it is now possible to move the shutter into its first position, in which it protects the substrates against the impingement of contaminations and electrons. In this case, a single shutter with a single actuator is associated with to a plurality of detectors or substrates, such that a plurality of detectors can be protected by the actuation of the single actuator.

In accordance with one embodiment herein, the shutter also provides the function of a collimator, which restricts or defines a solid angle range from which the detector can receive X-ray radiation. Said solid angle range contains a region of the object around the point of intersection between the optical axis and the object plane in order to receive the desired X-ray radiation that is caused by the impinging particle beam and emerges from the object, wherein the solid angle range, in accordance with the structural space available for the shutter, is restricted as far as possible in order that the impingement of X-ray radiation which does not originate from the object, such as, for example, stray radiation that arises at the pole pieces of the magnetic lens, is not permitted to pass to the detector. For this purpose, the shutter may comprise a shutter surface which is arranged at a distance from the substrate and has an aperture which allows X-ray radiation to pass through towards the respective detector only in the second position. A cross-sectional area of the aperture can be, in particular, significantly smaller than a cross-sectional area of the associated substrate in order to significantly restrict the solid angle range from which X-ray radiation can impinge on the detector.

In accordance with one embodiment herein, the shutter comprises a tubular piece, which in the second position of the shutter extends from the aperture towards the substrate of the detector. Said tubular piece can, in particular, expand conically proceeding from the aperture towards the substrate.

In accordance with embodiments, the substrate areas of the detectors are comparatively small and have an area of less than 50 mm², and in particular less than 20 mm². In comparison with large-area detectors conventionally used, such small detectors allow a high energy resolution to be obtained in conjunction with low detector noise and low costs.

This makes it possible to arrange the detectors near the point of intersection between the optical axis and the object plane and, although the area of the substrates is comparatively small, nevertheless, as seen from the point of intersection, to cover a comparatively large solid angle range by the substrates of the detectors. Together with the provision of collimators whose openings facing the object, in accordance with the area of the substrates, are likewise comparatively small, this affords the advantage in comparison with large-area detector substrates arranged further away from the point of intersection between the optical axis and the object plane that an approximately identical solid angle range around the point of intersection can be covered with detection areas, and the impingement of undesired stray radiation on the detectors is significantly suppressed on account of the small diameters of the entrance cross sections of the collimators.

Distances between the substrates and the point of intersection between the optical axis and the object plane can be, for example, less than 12 mm or 20 mm.

### BRIEF DESCRIPTION OF THE DRAWINGS

The forgoing as well as other advantageous features of the invention will be more apparent from the following detailed description of exemplary embodiments of the invention with reference to the accompanying drawings. It is noted that not all possible embodiments of the present invention necessarily exhibit each and every, or any, of the advantages identified herein.

FIG. 1 is a schematic illustration of a particle beam microscope in a longitudinal section;

FIG. 2 is a schematic illustration of a detail from FIG. 1 for elucidating certain angular relations;

FIG. 3 is a schematic illustration of a cross section of the particle beam microscope shown in FIG. 1;

FIGS. 4a, 4b are plan views of a detector arrangement in two different positions of a shutter;

FIG. 5 is a schematic illustration of a longitudinal section through a shutter;

FIG. 6 is a plan view of the shutter shown in

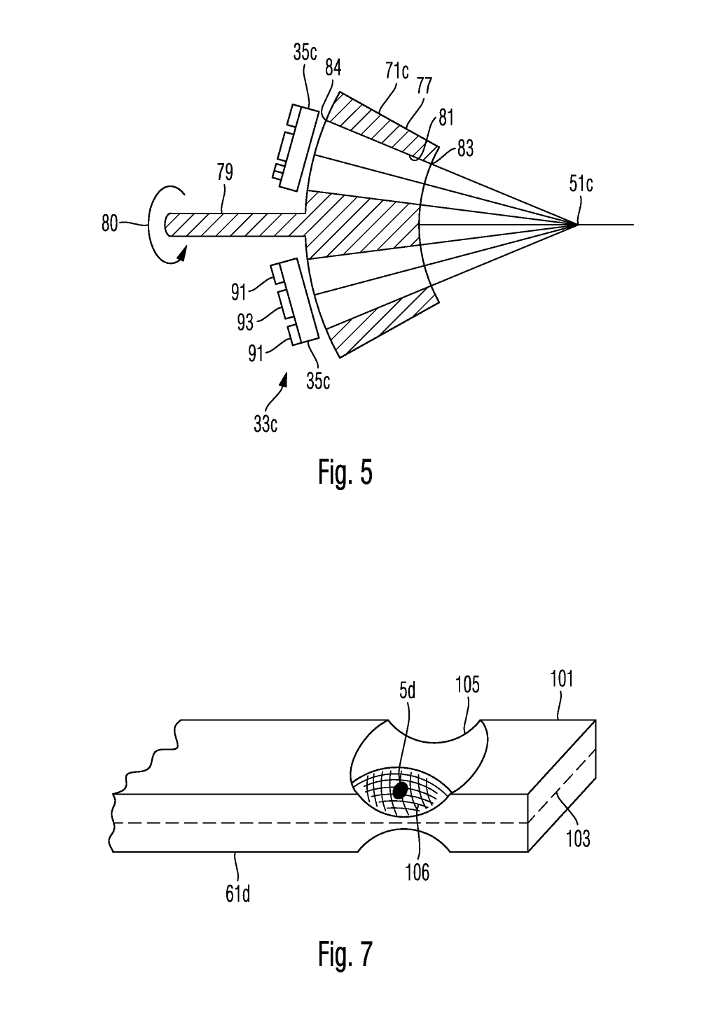

FIG. 5; and

FIG. 7 is a perspective illustration of a sample holder suitable for mounting an object to be inspected.

### DETAILED DESCRIPTION OF EXEMPLARY EMBODIMENTS

In the exemplary embodiments described below, components that are alike in function and structure are designated as far as possible by alike reference numerals. Therefore, to understand the features of the individual components of a specific embodiment, the descriptions of other embodiments and of the summary of the invention should be referred to.

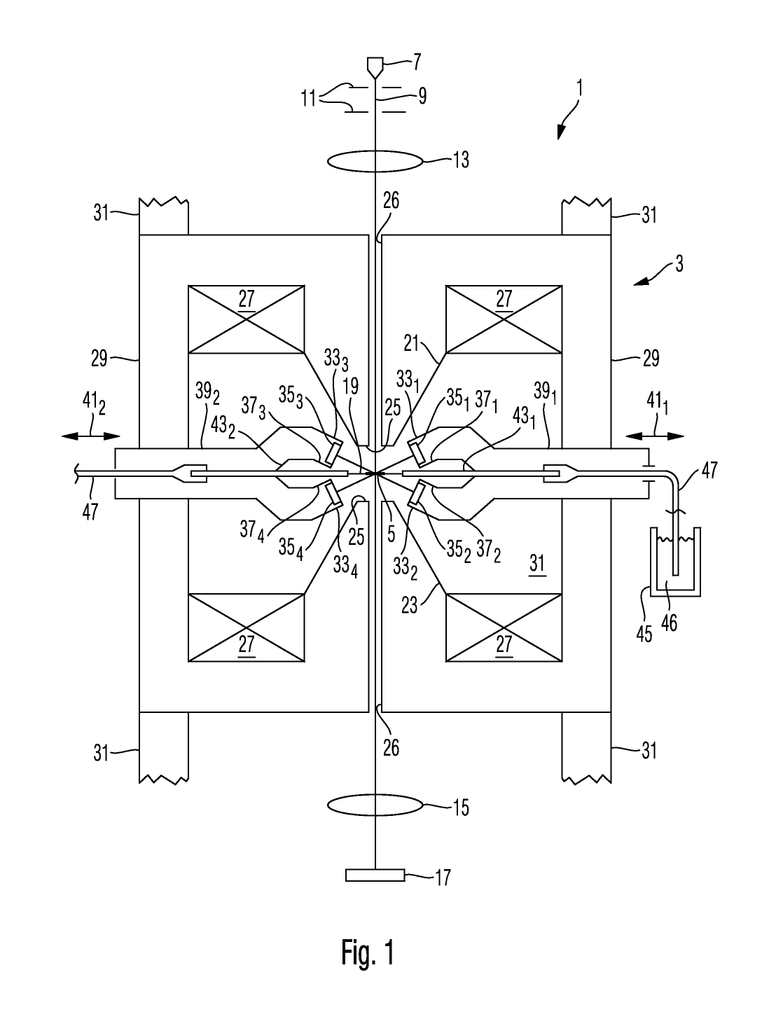

FIG. 1 is a schematic illustration of a particle beam microscope 1 designed as a transmission electron microscope, wherein the illustration shows an electron-optical lens 3, which generates a focusing magnetic field in the region of an object 5 to be examined, schematically in longitudinal section and further components of the electron microscope 1 functionally in schematic fashion. The electron microscope 1 comprises an electron beam source for generating an electron beam 9, a plurality of electrodes 11 for shaping and accelerating the beam 9, and one or more condenser lenses 13 or other electron-optical components for further shaping and manipulating the beam 9 before the latter enters into the lens 3. The further components can comprise, for example, a monochromator, a corrector for correcting optical aberrations of the lens 3, and deflectors for scanning the beam 9 over the object 5.

In the beam path downstream of the lens 3, it is possible to arrange further electron-optical components 15, such as projective lenses, diaphragms, phase plates, biprisms, correctors, spectrometers and the like, and finally one or more detectors 17.

The objective lens 3 focuses the electron beam 9 in an object plane 19, in which the object 5 to be examined is arranged. The beam 9 passes through the object 5, wherein interactions between the object and the beam influence the latter for example with regard to the kinetic energies or the trajectories of the electrons of the beam.

Such influences are detected by the one or the plurality of detectors 17 and evaluated in order to obtain therefrom information about the object.

The lens 3 generates a magnetic field that focuses the electron beam 9 between two pole pieces 21, 23, of which one (21) is arranged in the beam path upstream of the object plane 19 and the other (23) is arranged in the beam path downstream of the object plane. The pole pieces 21, 23 each have a through-hole 26, through which the electron beam 9 passes. Furthermore, the pole pieces 21, 23 in each case taper towards the object plane 19 and in each case have an end surface 25 facing the object plane 19, from which field lines of the focusing magnetic field exit and enter, respectively. The magnetic field is generated by windings 27 through which current flows and which surround the pole pieces 21 and 23 in a ring-shaped fashion. The magnetic flux between the pole pieces 21 and 23 is closed by means of a cylindrical metallic yoke 29, which also delimits a vacuum area 31 surrounding the object 5. Further components 31 of the vacuum enclosure adjoin the yoke 29 upwards towards the electron source 7 and downwards towards the detector 17 in the illustration in FIG. 1, such that the electron source 7 and the detector 17 are also arranged in the vacuum.

X-Ray detectors 33₁, 33₂, 33₃ and 33₄ are furthermore arranged in the vacuum area 31 in the vicinity of the object 5, in order to detect X-ray radiation which is generated by the electron beam 9 as a result of the impingement thereof on the object 5. The X-ray detectors 33 respectively comprise a radiation-sensitive substrate 35₁, 35₂, 35₃ and 35₄, which is designed for detecting X-ray radiation and generating electrical signals which in each case represent the energy of detected X-ray quanta. The substrates 35 are respectively mounted by means of mounts 37₁, 37₂, 37₃ and 37₄ such that they are arranged at predetermined distances from and orientations with respect to the object 5, as will be described in even greater detail below. In particular, one or a plurality of substrates 35₁, 35₃ are arranged upstream of the object plane as seen in the beam direction, and one or a plurality of substrates 35₂, 35₄ are arranged downstream of the object plane as seen in the beam direction.

The two X-ray detectors 33₁ and 33₂ are jointly mounted on a tube 39₁, which extends through the vacuum enclosure or the yoke 29 and is sealed relative thereto. The tube 39₁ can be moved to and fro in a direction represented by an arrow 41₁, in order to displace the detectors 31₁ and 31₂ from their measurement position illustrated in FIG. 1, in which measurement position the substrates 35₁, 35₂ of the detectors 33₁, 33₂ are arranged near the object 5, into a parking position drawn back further away from said object. In a similar manner, the detectors 33₃ and 33₄ are mounted on a tube 39₂, which likewise passes through the vacuum enclosure 29 and is sealed relative thereto, and can be moved in a direction represented by an arrow 41₂ in order also to move the detectors 33₃ and 33₄ from a measurement position near the object 5 into a parking position drawn back at a distance from said object. The detectors 33 are moved into the measurement position if the detectors are intended to detect X-ray radiation generated by the impingement of the electron beam 9 on the object 5. The detectors 33 are arranged in the parking position if X-ray radiation is not intended to be detected, such that possibly other components such as, for example, other detectors, heat sinks or diaphragms can be arranged near the object.

A cooling plate 43₁ is arranged between the two detectors 33₁ and 33₂, said cooling plate being in contact with a cold reservoir 45 of liquid nitrogen 46, for example, via a cold conductor 47, such as a flexible copper multiple-stranded wire, for example. The cooling plate 43₁ is provided for cooling a vicinity around the object 5 and the detectors 33₁, 33₂ and also to withdraw contaminants in particular from the vacuum area 31 around the detectors 33₁ and 33₂, in order that said contaminants are not adsorbed on the surfaces of the substrates 35₁ and 35₂. In a similar manner, a cooling plate 43₂ is arranged between the detectors 33₃ and 33₄, said cooling plate likewise being in contact with a cold reservoir 45.

Electrical lines such as, for example, voltage supply lines and signal lines for the operation of the X-ray detectors are led from the vacuum area 31 towards the outside through the tube 39 and are not illustrated in FIG. 1.

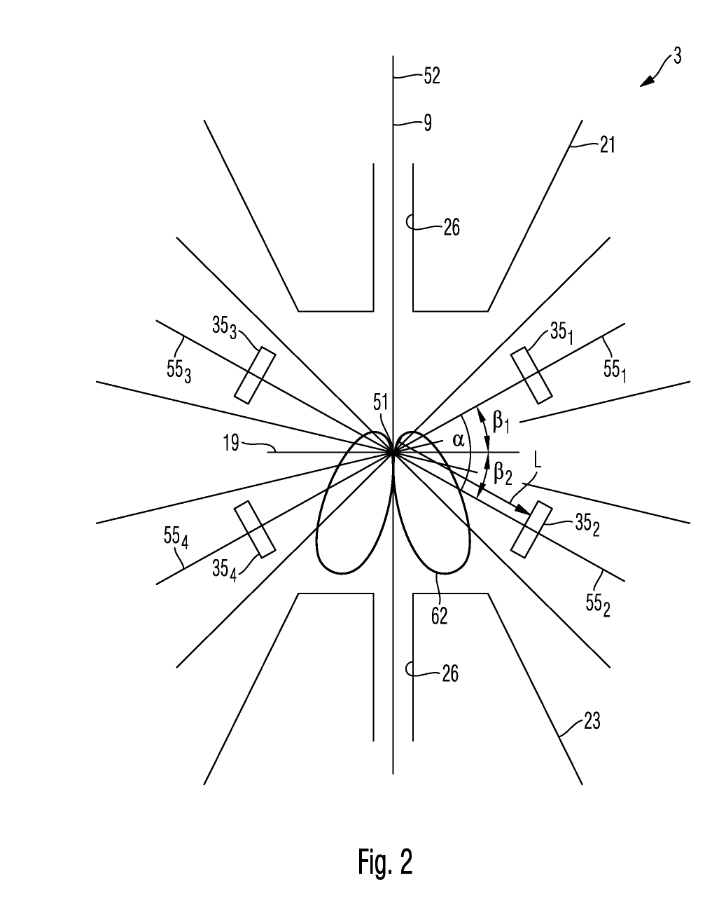

FIG. 2 is a schematic illustration for elucidating the arrangement of the substrates 35 of the X-ray detectors 33 with respect to a point of intersection 51 between the object plane 19 and an axis 53 of symmetry of the pole pieces 21, 23, which is simultaneously also the optical axis of the lens 3 and along which the electron beam 9 runs, wherein the latter can be deflected with respect to the axis 53 in order to scan it over the object arranged in the object plane 19.

FIG. 2 illustrates straight lines 55₁, 55₂, 55₃ and 55₄ which in each case extend through the point of intersection 51 between the optical axis 53 and the object plane 19 and a centre of one of the substrates 35₁, 35₂, 35₃ and 35₄, respectively. Main surfaces of the substrates 35 can be oriented orthogonally with respect to the straight lines 55, although this need not be the case. Furthermore, the substrates 35 are in each case arranged at a distance L from the point of intersection 51 between the optical axis 53 and the object plane 19. Consequently, relative to the point of intersection 51 between the optical axis 53 and the object plane 19, each X-ray detector 33 covers a solid angle range Ω given approximately by Ω=A/L², where A is the cross-sectional area of the substrate 35.

An angle α that is greater than 14° and less than 90° is formed between the straight lines 55₁ and 55₂ through the centres of the substrates 35₁ and 35₂, respectively. Consequently, the substrates 35₁ and 35₂ are arranged at different elevation angles with respect to the object plane 19. This has the following advantage:

A line 62 in FIG. 2 represents a spatial intensity distribution of continuous bremsstrahlung which is generated by impingement of an electron beam with a kinetic energy of 60 keV on a thin object at the point of intersection 51 between the optical axis 53 and the object plane 19. This angular distribution is rotationally symmetrical with respect to the axis 53, although greatly dependent on the elevation angle with respect to the object plane 19. The two substrates 35₁ and 35₂ are exposed to different intensities of bremsstrahlung on account of the angle α between the straight lines 55₁ and 55₂ through the centres of the substrates. The bremsstrahlung detected by the detectors forms a background for the radiation which is actually intended to be detected and evaluated in order to obtain information about the irradiated object, namely the characteristic X-ray radiation. The latter is generated at the point of intersection 51 between the optical axis 53 and the object plane 19 with a substantially isotropic spatial intensity distribution, such that both substrates 35₁ and 35₂ detect approximately identical proportions of characteristic X-ray radiation.

By jointly adapting the bremsstrahlung background in the spectra generated by the substrates 35₁ and 35₂, it is possible to determine the background particularly precisely and to remove it from the spectra, such that the remaining signal components in the spectra substantially exclusively represent the characteristic X-ray radiation generated at the object.

In the exemplary embodiment illustrated in FIG. 1, the two substrates 35₁ and 35₂ are arranged not only at different elevation angles with respect to the object plane 19, but also on different sides of the object plane. Thus, an elevation angle β₁ of the straight line 55₁ can lie in a range of −45° to −7° and an elevation angle β₂ of the straight line 55₂, in a range of +7° to +45° with respect to the object plane.

In particular, the at least one X-ray detector arranged downstream of the object plane in the beam direction of the particle beam or electron beam can be arranged at an elevation angle with respect to the object plane whose absolute value is greater than the absolute value of the elevation angle of the at least one X-ray detector arranged upstream of the object plane in the beam direction of the particle beam or electron beam.

This affords advantages in particular in the case of X-ray detectors which have a sensitivity which is dependent on the energy of the X-ray quanta and which decreases with increasing quantum energy of the X-ray quanta, as is the case for example for silicon drift detectors. This is because since the bremsstrahlung generated in the forward direction at the object is angle- and energy-dependent in such a way that principally higher-energy X-ray radiation emerges from the object at relatively large angles with respect to the optical axis, the bremsstrahlung background detected by the X-ray detectors arranged in the forward direction is smaller if the elevation angle at which the X-ray detectors arranged in the forward direction are arranged is larger with regard to its absolute value.

In the exemplary embodiment illustrated, furthermore, the substrate 35₃ is arranged in a manner lying diametrically opposite the substrate 35₂ with respect to the point of intersection between the optical axis 53 and the object plane 19, and the substrate 35₄ is arranged in a manner lying diametrically opposite the substrate 35₁ with respect to the point of intersection 51. In other exemplary embodiments, an angle between the straight line 55₃ and the straight line 55₄ likewise lies in a range of more than 14° and less than 90°. Likewise, an elevation angle of the straight line 55₃ with respect to the object plane 19 can lie in a range of −45° to −7°, and an elevation angle of the straight line 55₄ with respect to the object plane 19 can lie in a range of +7° to +45°.

In the exemplary embodiment illustrated, the object plane 19 is arranged centrally between the pole pieces 21 and 23, and the construction of the lens 3 is also approximately symmetrical with respect to the object plane 19. However, this is not necessarily the case. Rather, the construction of the lens 3 can also be asymmetrical with respect to the object plane 19, such that the object plane 19 is arranged, for example, nearer to the rear pole piece 23 than to the front pole piece 21.

Further embodiments of the invention are described below, wherein components which correspond to those of the embodiment described with reference to FIGS. 1 and 2 with regard to their construction and their function are identified by the same reference symbols and supplemented by an additional letter for distinguishing purposes.

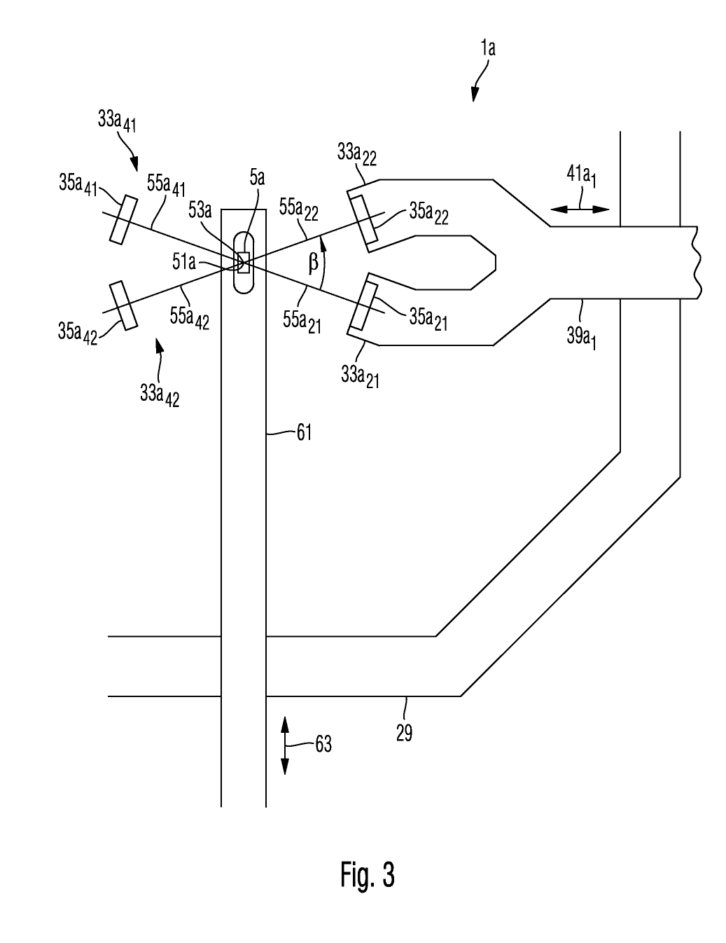

FIG. 3 is a schematic illustration of an electron microscope 1a in cross section parallel to an object plane of the microscope. The electron microscope 1a also has a plurality of X-ray detectors arranged at different elevation angles with respect to the object plane. The sectional illustration in FIG. 3 shows two X-ray detectors 33a₂₁ and 33a₂₂ having respective substrates 35a₂₁ and 35a₂₂. Straight lines 55a₂₁ and 55a₂₂ which extend through the point of intersection 51a between the optical axis 53a of the lens and the object plane and through a centre of the respective substrate 35a₂₁ and 35a₂₂ form an angle β in projection onto the object plane, which angle can lie in a range of 7° to 83°.

In FIG. 3 furthermore two substrates 35a₄₁ and 35a₄₂ of two further detectors are shown. The latter are arranged with respect to the point of intersection 51a between the optical axis 53a and the object plane in such a way that a straight line 55a₄₁ through the point of intersection 51a and the centre of the substrate 35a₄₁ coincides with the straight line 55a₂₁, and that a straight line 55a₄₂ through the point of intersection 51a and the centre of the substrate 35a₄₂ in projection onto the object plane coincides with the straight line 55a₂₂. With respect to the point of intersection 51a between the optical axis 53 and the object plane 19, the substrate 35a₄₁ is arranged diametrically opposite a substrate of an X-ray detector not illustrated in FIG. 3. Likewise, the other substrates 35a₄₂, 35a₂₂ and 35a₂₁ are respectively arranged diametrically opposite substrates of further X-ray detectors that are not illustrated in FIG. 3.

FIG. 3 furthermore shows a sample holder 61, which passes through the vacuum enclosure 29 and is movable at least in a direction represented by an arrow 63, in order to arrange the object 5a at the point of intersection 51a between the object plane and the optical axis 53a, such that the object 5a can be scanned by the electron beam, wherein the characteristic X-ray radiation generated is detected by the detectors.

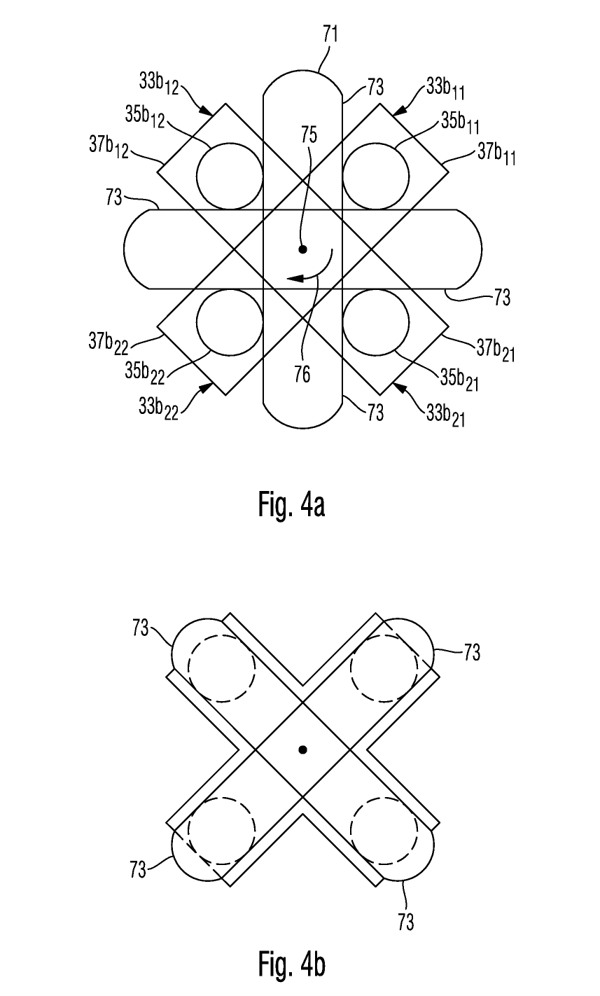

FIG. 4a shows a plan view of substrates 35b₁₁, 35b₂₂, 35b₁₂ and 35b₂₂ of X-ray detectors 33b₁₁, 33b₂₁, 33b₁₂ and 33b₂₂ of an electron microscope of a further embodiment. In this case, the substrates 35b₁₁ and 35b₁₂ are arranged upstream of the object plane, as seen in the direction of the beam path of the electron microscope, while the substrates 35b₂₁ and 35b₂₂ are arranged downstream of the object plane.

The four substrates 35b can be covered by a common shutter 71, in order to protect them against contaminants and impinging electrons and if a measurement of the X-ray radiation by the detectors 33b is not desired. The shutter has four blades 73 arranged in cruciform fashion and fixedly connected to one another and is rotatable about a rotation spindle 75 by a drive, as is indicated by an arrow 76 in FIGS. 4a and 4b. In the situation shown in FIG. 4a, the blades 73 are respectively arranged between two substrates 35b, such that they do not cover the latter and the measurement of X-ray radiation is possible.

FIG. 4b shows the operating mode in which the substrates 35b of the detectors 33b are respectively covered by a blade 73 of the shutter 71, in order to protect them against contamination with contaminants and the impingement of electrons.

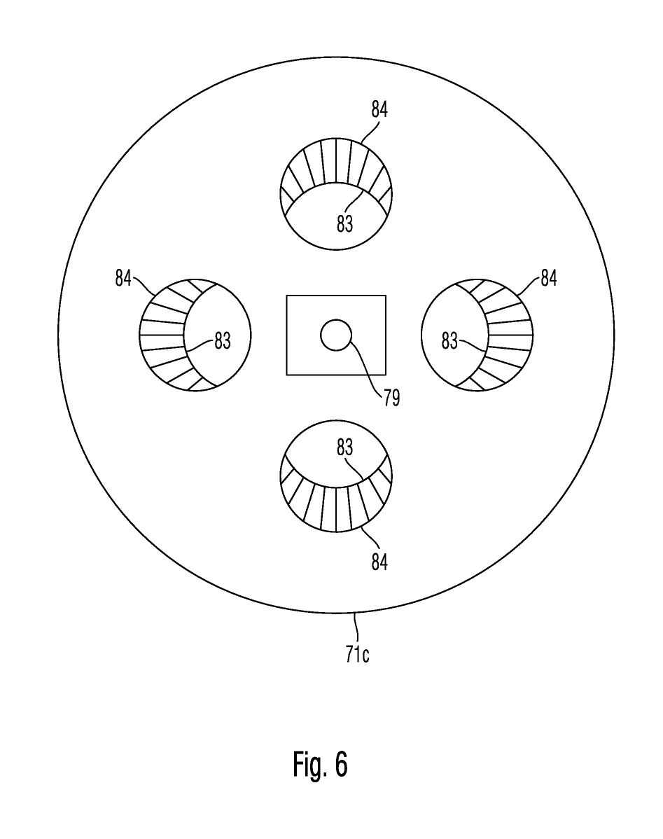

FIGS. 5 and 6 show a further embodiment of a shutter for protecting four substrates 35c against the impingement of contaminants and electrons. In this case, FIG. 5 is a schematic sectional illustration through the shutter 71c, while FIG. 6 is a schematic plan view of a side of the shutter 71c that faces the substrates.

The shutter is formed by a material block 77, which is mounted such that it is rotatable about a rotation spindle 79, as is indicated by an arrow 80. The material block 77 has four through-openings 81, the cross section of which in each case tapers conically proceeding from a substrate 35c towards a point of intersection 51c between the object plane and the optical axis of the electron microscope. The four through-holes 81 thus form four tubular pieces each having an opening 83 facing the point of intersection 51c between the optical axis and the object plane and an opening 84 facing the substrate 35c. The opening 84 facing the substrate 35c has a cross-sectional area approximately corresponding to the cross-sectional area of the substrate 35c. By contrast, the opening 83 facing away from the substrate 35c has a cross-sectional area that is significantly smaller than the cross-sectional area of the opening 84 facing the substrate 35c. Furthermore, a length of the tubular pieces or a distance between the openings 83 and 84 is greater than 0.6 times, and in particular greater than 0.9 times, a diameter of the substrate 35c. Therefore, the tubular pieces of the shutter 71c in each case act as a collimator for one of the detectors in order to suppress the impingement of stray radiation on the substrate 35c of the detector.

FIG. 5 illustrates the operating mode in which X-ray radiation emerging from the point of intersection 51c between the optical axis and the object plane is intended to be detected by the detectors. As a result of the shutter 71c being rotated in the direction of the arrow 80 by the driving of the spindle 79 by 45°, for example, it is possible to position the shutter 71 such that the material block 77 blocks the impingement of X-ray radiation emerging from the point of intersection 51c between the optical axis and the object plane on the substrates 35c of the detectors.

The X-ray detectors can be silicon drift detectors. In this respect, FIG. 5 shows Peltier elements 91, which are in thermally conductive contact with the substrates in order to cool the latter. By way of example, the Peltier elements 91 are designed such that the substrates can be operated at a temperature of −20° Celsius. The reference symbols 93 in FIG. 5 designate an electronic unit of the detector 33c that is assigned to the substrate 35c.

FIG. 7 is a simplified perspective illustration of a sample holder 61d, which can be used for mounting an object 5d to be examined in an object plane of an electron microscope. The sample holder 61d comprises a rod 101 of rectangular cross section, for example, which can be produced from metal, for example. The rod 101 has cutouts or apertures 105 which are symmetrical with respect to a central plane 103 of the rod and which define a through-hole in which a net 106 is arranged, on which the object 5d is fitted in order to arrange it in the object plane of the electron microscope.

In this case, the apertures 105 are embodied such that X-ray radiation emerging from the object 5d can pass towards the X-ray detectors, without being shaded by the material of the rod 101.

The particle beam microscopes described in the embodiments explained above are transmission electron microscopes whose electron detector is arranged on an opposite side with respect to the object plane of the electron source and detects electrons transmitted by the object. However, the present disclosure is not restricted thereto. Rather, the described configuration of X-ray detectors can also be used on other types of electron microscopes in which an electron detector is arranged on a same side as the electron source with respect to the object plane and detects electrons, such as backscattered electrons and secondary electrons, for example, which are caused by primary electrons impinging on the object.

The magnetic lens used for focusing the particle beam onto the object can be used in combination with a likewise focusing electrostatic lens.

The particle beam microscopes described in the embodiments explained above have magnetic lenses having a pole piece arranged in the beam path upstream of the object and a pole piece arranged in the beam path downstream of the object. In accordance with other embodiments provided, both pole pieces of the magnetic lens that focuses the beam onto the object are arranged in the beam path upstream of the object.

In the embodiments explained above, the particle beam microscopes explained are transmission electron microscopes by way of example. However, the present disclosure is not restricted thereto. In accordance with other exemplary embodiments, the particle beam microscope can also comprise a scanning electron microscope in which a focused electron beam is scanned over the object and the interaction products initiated or generated by the electron beam at the object are detected for image generating purposes in a manner dependent on the position at which the electron beam impinges on the sample.

In accordance with other exemplary embodiments, the particle beam microscope can also comprise an ion microscope, such as a gas field ion microscope, for example, in which a particle beam is generated by gas atoms being ionized in an electrostatic field of an emission tip. The object is then irradiated with the ion beam, and the X-ray quanta arise as a result of the interaction of the ions of the ion beam with the atoms of the object. If the particle beam microscope is designed as an ion microscope, the objective lens need not necessarily be a magnetic lens, but rather can also be an electrostatic objective lens, which then has no pole pieces.

While the invention has been described with respect to certain exemplary embodiments thereof, it is evident that many alternatives, modifications and variations will be apparent to those skilled in the art. Accordingly, the exemplary embodiments of the invention set forth herein are intended to be illustrative and not limiting in any way. Various changes may be made without departing from the spirit and scope of the present invention as defined in the following claims.

1-20. (canceled)

21. A particle beam microscope having a beam path, the microscope comprising:
a magnetic lens having an optical axis and at least one front pole piece arranged in the beam path along the optical axis at a distance upstream of an object plane;
an object holder, which is configured for mounting an object to be inspected at a point of intersection between the optical axis and the object plane;
a first X-ray detector having a first radiation-sensitive substrate; and
a second X-ray detector having a second radiation-sensitive substrate,
wherein the first and second X-ray detectors are arranged such that a first elevation angle between a first straight line extending through the point of intersection and a centre of the first substrate and the object plane differs from a second elevation angle between a second straight line extending through the point of intersection and a centre of the second substrate and the object plane by more than 14°.

22. The particle beam microscope according to claim 21, wherein the first elevation angle is within a range from −45° to −7° and the second elevation angle is within a range from +7° to +45°.

23. The particle beam microscope according to claim 21, further comprising:
a third X-ray detector having a third radiation-sensitive substrate, and
a fourth X-ray detector having a fourth radiation-sensitive substrate,
wherein the third and fourth X-ray detectors are arranged such that a third elevation angle between a third straight line extending through the point of intersection and a centre of the third substrate and the object plane differs from a fourth elevation angle between a fourth straight line extending through the point of intersection and a centre of the fourth substrate and the object plane by more than 14°.

24. The particle beam microscope according to claim 23, wherein the first and third X-ray detectors are arranged such that the third elevation angle is equal to the first elevation angle.

25. The particle beam microscope according to claim 23, wherein the second and fourth X-ray detectors are arranged such that the fourth elevation angle is equal to the second elevation angle.

26. The particle beam microscope according to claim 23, wherein the first and third X-ray detectors are arranged such that at least one of the first and third straight lines, and the second and fourth straight lines substantially coincide when seen in a projection onto the object plane.

27. A particle beam microscope having a beam path, the microscope comprising:
a magnetic lens having an optical axis and at least one front pole piece arranged in the beam path along the optical axis at a distance upstream of an object plane;
an object holder, which is configured for mounting an object to be inspected at a point of intersection between the optical axis and the object plane;
a first X-ray detector having a first radiation-sensitive substrate;
a second X-ray detector having a second radiation-sensitive substrate; and
an actuator; and
a shutter which can be moved from a first position to a second position by the actuator;
wherein the shutter is configured and arranged such that the shutter, when it is in the first position, is arranged between the point of intersection and the first and second substrates in order to prevent incidence of X-ray radiation emerging from the object arranged at the point of intersection on the first and second substrates, and such that the X-ray radiation emerging from the object can impinge on the first and the second substrates when the shutter is in the second position.

28. The particle beam microscope according to claim 27, wherein the shutter comprises a shutter surface, wherein the shutter surface is, when the shutter is in the first position, at a distance from the first substrate which is greater than 0.6 times a diameter of the substrate, and wherein the shutter surface has first and second apertures which can be traversed by X-ray radiation emerging from the object towards the first and second substrates, when the shutter is in the second position.

29. The particle beam microscope according to claim 28, wherein the shutter comprises a first tubular piece extending from the first aperture towards the first substrate, when the shutter is in the second position, and a second tubular piece extending from the second aperture towards the second substrate, when the shutter is in the second position.

30. The particle beam microscope according to claim 29, wherein the first and second tubular pieces have a conical shape having an inner diameter which increases with decreasing distance from the respective substrate.

31. A particle beam microscope having a beam path, the microscope comprising:
a magnetic lens having an optical axis and at least one front pole piece arranged in the beam path along the optical axis at a distance upstream of an object plane;
an object holder, which is configured for mounting an object to be inspected at a point of intersection between the optical axis and the object plane;
a first X-ray detector having a first radiation-sensitive substrate;
a second X-ray detector having a second radiation-sensitive substrate;
a vacuum enclosure defining a vacuum space containing the point of intersection; and
a mount carrying the first and second X-ray detectors and which comprising a tube extending through the vacuum enclosure, wherein the mount is displaceable in a longitudinal direction in order to move the first and second X-ray detectors from a measuring position near the point of intersection to a parking position further away from the point of intersection.

32. The particle beam microscope according to claim 21, wherein the first and second substrates each have a substrate area of greater than 5 mm2.

33. The particle beam microscope according to claim 21, wherein the first and second substrates each have a substrate area of less than 50 mm2.

34. The particle beam microscope according to claim 21, wherein at least one of a distance between the first substrate and the point of intersection and a distance between the second substrate and the point of intersection is less than 12 mm.

35. The particle beam microscope according to claim 21, wherein the X-ray detector is a silicon drift detector.

36. The particle beam microscope according to claim 21, wherein the X-ray detector comprises at least one Peltier element configured to cool the substrate.

37. The particle beam microscope according to claim 21, further comprising at least one cooling plate which is arranged near the first and second X-ray detectors and which is thermally conductively connected to a reservoir designed for receiving liquid nitrogen.

38. The particle beam microscope according to claim 21, wherein the magnetic lens comprises a rear pole piece arranged in the beam path downstream of the object plane at a distance of less than 50 mm from the object plane.

39. The particle beam microscope according to claim 21, further comprising a controller configured to determine a proportion of bremsstrahlung contained in first and second recorded X-ray spectra, wherein the first X-ray spectrum is detected by the first X-ray detector and associated with a location of an object, and wherein the second X-ray spectrum is detected by the second X-ray detector and associated with the same location of the object.

40. The particle beam microscope according to claim 39, wherein the determined proportion of bremsstrahlung is coherent bremsstrahlung.
